(19) United States
(12) Patent Application Publication
(10) Pub. No.: US 2025/0107340 A1
(43) Pub. Date: Mar. 27, 2025

(54) LIGHT-EMITTING DEVICE AND METHOD FOR MANUFACTURING THE LIGHT-EMITTING DEVICE

(71) Applicant: Sharp Display Technology Corporation, Kameyama City, Mie (JP)

(72) Inventor: Bai ZHANG, Kameyama City, Mie (JP)

(21) Appl. No.: 18/715,516

(22) PCT Filed: Jan. 31, 2022
(86) PCT No.: PCT/JP2022/003555

§ 371 Date: May 31, 2024

(51) Int. Cl. H10K 59/122; H10K 50/11; H10K 59/12; H10K 85/60

(52) U.S. Cl. CPC H10K 59/122; H10K 50/11; H10K 59/1201; H10K 85/60; H10K 85/654

(57) ABSTRACT

A display device includes a bank having an opening from which the upper surface of an anode is exposed, and provided with an inclined opening sidewall. The bank has a plurality of protrusions having upper surfaces that are horizontal, and formed in a staircase manner along the opening sidewall. Within the opening, organic molecules constituting an EL layer are accumulated perpendicularly to accumulation surfaces while being oriented horizontally so that the direction of their long axes is in a horizontal direction.

### TECHNICAL FIELD

The present disclosure relates to a light-emitting device and a method for manufacturing the same.

### BACKGROUND ART

Patent Literature 1 discloses controlling the molecule orientation of the compound molecules of the light-emitting material of an organic light-emitting element horizontally by using an orientation control agent in combination. In Patent Literature 1, controlling the molecule orientation of the light-emitting material horizontally can align, near the direction of the normal to a film formation surface, the traveling directions of light emitted from the compound molecules of the light-emitting material. This improves the efficiency of light extraction from the light exit surface of the organic light-emitting element and can thus achieve high external efficiency.

### CITATION LIST

### Patent Literatures

Patent Literature 1: Japanese Unexamined Patent Application Publication No. 2019-112572

Patent Literature 2: International Publication No. 2009/147838

Patent Literature 3: Japanese Unexamined Patent Application Publication No. 2007-311235

Patent Literature 4: Japanese Unexamined Patent Application Publication No. 2018-6067

### SUMMARY

### Technical Field

However, as described in Patent Literatures 2 to 4 for instance, organic layers, such as organic light-emitting layers, are formed in many cases by applying a coating liquid containing an organic compound and a solvent into a region defined all around by a bank. Further, a display device provided with a plurality of display elements includes a lower electrode patterned as a pixel electrode for each pixel. The edge of the electrode patterned for each pixel is covered with a bank, called an edge cover, in order to avoid electric-field concentration. In either case, the bank is formed in a tapered shape and has an inclined opening sidewall.

Hence, the organic molecules constituting the foregoing organic layer accumulate on the bank while being oriented parallel to the inclined opening sidewall. Thus, even in the same opening inside of the bank, a direction in which the organic film grows is different between the vicinity of the bank's edge and the center of the bank's opening (i.e., the center of an emission region).

The mobility of electrons or holes (electric-charge mobility) lowers further near the bank's edge than that at the center of the bank's opening (i.e., at the center of the emission region), because the organic molecules are not oriented horizontally. This lowering adversely affects electron-and-hole carrier balance, light emission efficiency, and light extraction near the bank's edge. This makes a light-emission-efficiency difference and a luminance difference between the vicinity of the bank's edge and the center of the bank's opening, and thus, a light-emitting device, such as the foregoing light-emitting element or the foregoing display device, cannot emit light uniformly.

None of Patent Literatures 1 to 4 solves the above-mentioned problem. Patent Literatures 1 to 4 neither disclose nor suggest an orientation direction of organic molecules constituting an organic layer provided within the opening of a bank having an inclined opening sidewall.

One aspect of the present disclosure has been made in view of the above problem and aims to provide a light-emitting device in which organic molecules constituting an organic layer provided within the opening of a bank having an inclined opening sidewall are oriented horizontally, so that the light-emitting device emits light uniformly, and the aspect aims to provide a method for manufacturing this light-emitting device.

### Solution to Problem

To solve the above problem, a light-emitting device according to one aspect of the present disclosure includes the following: a first electrode; a bank covering an edge of the first electrode, and having an opening from which an upper surface of the first electrode is exposed, the opening having an opening sidewall that is inclined; at least one organic layer provided within the opening and including at least a light-emitting layer; and a second electrode provided on the at least one organic layer, wherein the bank has a plurality of protrusions having upper surfaces that are horizontal, and formed in a staircase manner along the opening sidewall in such a manner that accumulation surfaces of organic molecules constituting the at least one organic layer are all horizontal, and the organic molecules are accumulated on the accumulation surfaces perpendicularly to the accumulation surfaces while being oriented horizontally so that a direction of long axes of the organic molecules is in a horizontal direction.

To solve the above problem, a method for manufacturing a light-emitting device according to one aspect of the present disclosure is a method for manufacturing the light-emitting device according to the aspect of the present disclosure. The method includes the following steps: forming the first electrode; forming the bank; forming the at least one organic layer; and forming the second electrode, wherein the step of forming the bank includes the following: a step forming a first resist film composed of a positive resist, so as to cover the first electrode; a step of patterning the first resist film so as to have the opening sidewall that is inclined and have the opening from which the upper surface of the first electrode is exposed, and so as to cover the edge of the first electrode; a step of forming a second resist film composed of a negative resist onto the first resist film patterned in the step of patterning the first resist film; and a step of patterning the second resist film so as to have the plurality of protrusions having upper surfaces that are horizontal, and formed in a staircase manner along the opening sidewall.

### Advantageous Effect of Disclosure

These aspects of the present disclosure can provide a light-emitting device in which organic molecules constituting an organic layer provided within the opening of a bank having an inclined opening sidewall are oriented horizontally, so that the light-emitting device emits light uniformly, and the aspects can provide a method for manufacturing this light-emitting device.

### BRIEF DESCRIPTION OF DRAWINGS

FIG. 1 is a schematic sectional view of an example of the schematic configuration of main components of a display device according to a first embodiment.

FIG. 2 is a plan view of the schematic configuration of a bank of the display device according to the first embodiment.

FIG. 3 is a sectional view of an opening of a comparative display device without protrusions on its bank and schematically illustrates how each organic molecule constituting an EL layer accumulates.

FIG. 4 is a sectional view of an opening of the display device according to the first embodiment and schematically illustrates how each organic molecule constituting an EL layer accumulates.

FIG. 5 is a flowchart showing an example of a method for manufacturing the display device according to the first embodiment.

FIG. 6 is sectional views of an example of the bank in the process of being formed in a step shown in FIG. 5.

FIG. 7 is a sectional view of the opening of the display device according to the first embodiment and schematically illustrates how each organic molecule constituting the EL layer accumulates.

FIG. 8 is a perspective view of the schematic configuration of main components of a domain restricting structure of a display device according to a second embodiment.

FIG. 9 is a plan view of the schematic configuration of the main components of the domain restricting structure of the display device according to the second embodiment.

FIG. 10 is a flowchart showing an example of a method for manufacturing the display device according to the second embodiment.

FIG. 11 is sectional views of the domain restricting structure in the process of being formed in exemplified part of a step shown in FIG. 10.

FIG. 12 is other sectional views of the domain restricting structure in the process of being formed in exemplified part of the step shown in FIG. 10.

### DESCRIPTION OF EMBODIMENTS

### First Embodiment

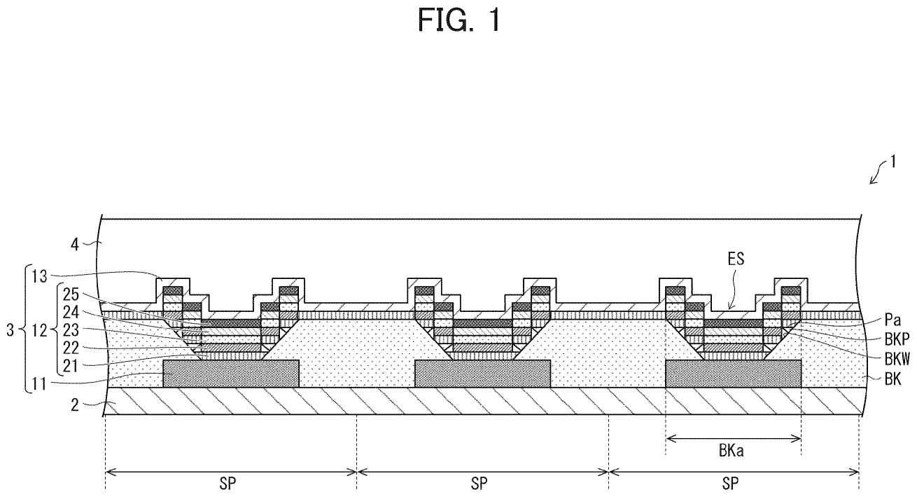

An embodiment of the present disclosure will be described below with reference to FIG. 1 to FIG. 6. It is noted that the following describes an instance where a light-emitting device according to this embodiment is a display device.

### Schematic Configuration of Display Device

FIG. 1 is a schematic sectional view of an example of the schematic configuration of main components of a display device 1 (light-emitting device) according to this embodiment.

The display device 1 has a plurality of subpixels SP. Each subpixel SP is provided with a light-emitting element ES. The display device 1 illustrated in FIG. 1 includes a substrate 2, which is an array substrate (circuit board), with a driving-element layer is formed thereon, and the display device 1 has a configuration in which a light-emitting element layer 3 including a plurality of light-emitting elements ES and a sealing layer 4 are stacked in the stated order on the substrate 2. The light-emitting element layer 3 is covered with the sealing layer 4. A functional film, not shown, having at least one of an optical-compensation function, a touch sensor function, and a protection function may be provided on the sealing layer 4, as necessary.

In this embodiment, a direction from the light-emitting elements ES of the display device 1 toward the substrate 2 of the display device 1 is referred to as a “downward direction”, and a direction from the substrate 2 toward the light-emitting elements ES is referred to as an “upward direction”. Also in this embodiment, a layer formed in a process step anterior to a process step of forming a comparative layer is referred to as a “lower layer”, and a layer formed in a process step posterior to the process step of forming the comparative layer is referred to as an “upper layer”.

The display device 1 includes, by way of example, the following subpixels SP for instance: a red subpixel that emits red light; a green subpixel that emits green light; and a blue subpixel that emits blue light. The red subpixel is provided with a red light-emitting element as the light-emitting element ES that emits red light. The blue subpixel is provided with a blue light-emitting element as the light-emitting element ES that emits blue light. The green subpixel is provided with a green light-emitting element as the light-emitting element ES that emits green light. However, the subpixel combination provided in the display device 1 is not limited to the above-described combination. The display device 1 may be a display device that emits single-color light. The display device 1 may also have a combination of the light-emitting elements ES (i.e., a combination of the subpixels SP) that emit light of colors other than the above-described combination when it is a color-display device having a plurality of light-emitting elements with different emission wavelengths.

The substrate 2 functions as a support for forming each layer of the light-emitting element ES. The substrate 2 has a configuration in which, for example, a TFT layer having a plurality of TFTs (thin-film transistors) is provided as a driving-element layer on, for example, an insulating substrate.

The display device 1 may be a flexible display device having flexibility and being thus bendable or may be an inflexible display device having rigidity and being thus not bendable. Accordingly, the insulating substrate may be an inorganic substrate made of an inorganic material, such as glass, quartz, or ceramics, or may be a flexible substrate mainly composed of a resin, such as polyethylene terephthalate or polyimide. When the insulating substrate is a flexible substrate, the insulating substrate may be composed of a resin film (plastic film), such as a polyimide film, or may be composed of two resin films and an inorganic insulating film sandwiched between these resin films.

Further, a barrier layer for preventing foreign substances, such as water and oxygen, from entering the TFT layer and light-emitting element layer 3 may be provided on the surface of the insulating substrate. Such a barrier layer can be composed of, for instance, a silicon oxide film, a silicon nitride film, or a silicon oxide nitride film, all of which are formed through chemical vapor deposition (CVD), or a stack of these films.

The TFT layer includes a subpixel circuit that controls the light-emitting element ES, and a plurality of wires connected to the subpixel circuit. The subpixel circuit is provided in the device's display region for each subpixel SP in correspondence with each subpixel SP. The subpixel circuit has a plurality of TFTs. The plurality of TFTs are electrically connected to a plurality of wires including gate wires, source wires, and other wires. These TFTs can have a publicly known structure; their structure is non-limiting.

On the surface of the TFT layer is a flattening film covering the plurality of TFTs and provided so as to flatten the surfaces of the plurality of TFTs. The flattening film can be composed of, for instance, an organic insulating material, such as polyimide resin or acrylic resin.

The light-emitting element layer 3 includes the plurality of light-emitting elements ES each provided in a corresponding one of the subpixels SP and has a conformation in which the individual layers of these light-emitting elements ES are stacked on the substrate 2.

The light-emitting element layer 3 includes the following: a plurality of anodes 11 provided on the flattening film; a cathode 13; an EL layer 12 (functional layer) provided between theses anode 11 and cathode 13; and an insulating bank BK. Each light-emitting element ES includes the anode 11, the EL layer 12, and the cathode 13.

In this embodiment, layers between the anode 11 and cathode 13 facing each other will be generically referred to as the EL layer 12. The light-emitting element ES is an organic light-emitting diode (OLED), and the EL layer 12 includes at least an organic layer. The EL layer 12 is composed of an organic layer in whole by way of example. The EL layer 12 includes at least a light-emitting layer (hereinafter, referred to as “EML”) 23.

The anode 11 is an electrode that supplies positive holes (holes) to the EML 23 in response to voltage application. The cathode 13 is an electrode that supplies electrons to the EML 23 in response to voltage application. The anode 11 and the cathode 13 are connected to a power source, not shown, so that a voltage is applied between them. The anode 11 and the cathode 13 each contain a conductive material and are each electrically connected to the EL layer 12.

At least one of the anode 11 and cathode 13 is a light-transparent electrode. It is noted that one of the anode 11 and cathode 13 may be a so-called reflective electrode having light reflectivity. The light-emitting element ES can extract light from near the light-transparent electrode.

The light-emitting element ES may be a bottom-emission light-emitting element that emits light from near a first electrode (lower electrode) that is either the anode 11 or cathode 13, whichever is lower. Alternatively, the light-emitting element ES may be a top-emission light-emitting element that emits light from near a second electrode (upper electrode) that is either the anode 11 or cathode 13, whichever is upper.

When the light-emitting element ES is a bottom-emission light-emitting element, a light-transparent electrode is used as the first electrode, and a reflective electrode is used as the second electrode. On the other hand, when the light-emitting element ES is a top-emission light-emitting element, a reflective electrode is used as the first electrode, and a light-transparent electrode is used as the second electrode.

The light-transparent electrode is composed of, for instance, a conductive light-transparent material, such as a thin film of indium tin oxide (ITO), a thin film of indium zinc oxide (IZO), a thin film of silver nanowires (Ag NWs), a thin film of magnesium-silver alloy (MgAg), or a thin film of Ag.

On the other hand, the reflective electrode is composed of a conductive light-reflective material, including a metal, such as Ag, Al, or Cu, and alloys containing these metals. It is noted that the reflective electrode may be a stack of a layer made of the foregoing light-transparent material, and a layer made of the foregoing light-reflective material.

The following describes an instance where, as illustrated in FIG. 1, the anode 11 is the first electrode, and the cathode 13 is the second electrode. However, the display device 1 is not limited to this instance; the cathode 13 may be the first electrode, and the anode 11 may be the second electrode.

The first electrode functions as a subpixel electrode (island-shaped lower electrode) and is provided in an island shape on the substrate 2 for each light-emitting element ES (i.e., for each subpixel SP). The second electrode is provided as a common electrode (common upper electrode) shared among all the light-emitting elements ES (i.e., all the subpixels SP) The light-emitting elements ES function as light sources for lighting the respective subpixels SP. The first electrodes are each electrically connected to the TFTs on the substrate 2.

The bank BK is used as an edge cover that covers the edge of the first electrode of each light-emitting element ES, and the bank BK functions as a subpixel separation film that partitions the subpixels SP adjacent to each other. Each subpixel SP is individually provided with the light-emitting element ES.

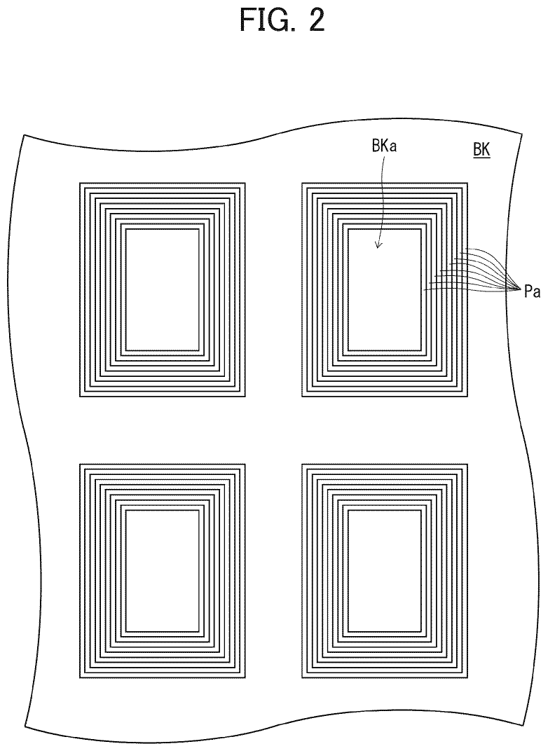

FIG. 2 is a plan view of the schematic configuration of the bank BK of the display device 1 according to the first embodiment.

The bank BK is provided along the edges of the first electrodes of the individual light-emitting elements ES, and as illustrated in FIG. 2, the bank BK is formed in, for instance, a lattice shape in plan view. The bank BK thus has a plurality of openings BKa from which the upper surfaces of the first electrodes are exposed. A single subpixel SP is provided with a single opening BKa.

As illustrated in FIG. 1, the inside of each opening BKa is provided with, as the EL layer 12, at least one organic layer including at least the EML 23.

It is noted that FIG. 2 illustrates, by way of example, an instance where each opening BKa is formed in a rectangular shape (oblong shape) in plan view. However, the shape of each opening BKa is non-limiting; each opening BKa may have a polygonal shape in plan view, such as a square shape, a rectangular shape, or a hexagonal shape, or each opening BKa may have a circular shape in plan view, such as an exactly circular shape or an elliptic shape.

As illustrated in FIG. 1, each opening BKa is formed in such a manner that its opening size (diameter) decreases toward its lower part. The bank BK thus has a forward-tapered cross-section so that the openings BKa having a reverse-tapered shape in sectional view are formed. As such, the bank BK has an inclined opening sidewall BKW as the inner wall of each opening BKa. It is noted that an angle (inclination angle) formed between the inclined surface of the bank BK (i.e., the inclined opening sidewall BKW) and the lower surface of the bank BK is non-limiting. Let the inclination angle be defined as) θ (°); in this case, θ preferably satisfies 1°≤θ≤89°, because an exemplified simulation reveals that such θ can prevent optical crosstalk. However, when the display device 1 is a high-definition OLED display device, a designated-luminance output at a small aperture ratio (area) of, for instance, θ<10° causes severe material deterioration, leading to lowering of the lifetime of the display device 1, and degradation of the product's quality. On the other hand, when the display device 1 is a high-definition OLED display device like this, an angle of θ>45° easily causes current leakage at the edge of the bank BK. Accordingly, θ more desirably satisfies 10≤θ≤45° and further desirably satisfies 20°≤θ≤30° in further view of, but not limited to, the photolithography process limitation in such a display device, and of current leakage that results from a large aperture ratio or θ.

Each opening sidewall BKW is provided with a plurality of protrusions BKP (stages). The plurality of protrusions BKP are formed in a staircase manner (i.e., in such a manner as to have differences in height) along the opening sidewall BKW in such a manner that the surfaces of the bank BK on which the organic molecules constituting the EL layer 12 accumulate are all horizontal, and each protrusion BKP has a horizontal upper surface Pa. As such, each opening BKa has a configuration in which, when viewed from immediately above, only the upper surface of the first electrode, an example of which is the anode 11, and the upper surfaces Pa of the protrusions BKP are exposed, as illustrated in FIG. 2, before the formation of the EL layer 12, and in which these accumulation surfaces of the organic molecules are all horizontal. It is noted that for convenience in illustration, all the drawings pertaining to this embodiment illustrate a reduced number of protrusions BKP.

The bank BK is made of an organic insulating material for instance. The organic insulating material preferably contains photosensitive resin. Examples of the organic insulating material include polyimide resin and acrylic resin.

The EL layer 12 needs to have at least one organic layer including at least the EML 23; the EL layer 12 may be a single layer consisting of only the EML 23, or a multi-layer including the EL layer 12 other than the EML 23. Examples of the EL layer 12 other than the EML 23 include a hole injection layer, a hole transport layer, an electron transport layer, and an electron injection layer. Hereinafter, a hole injection layer will be referred to as HIL, and a hole transport layer will be referred to as HTL. In addition, an electron transport layer will be referred to as ETL, and an electron injection layer will be referred to as EIL.

Each light-emitting element ES illustrated in FIG. 1 includes, as the EL layer 12, an HIL 21, an HTL 22, and the EML 23, an ETL 24, and an EIL 25. The light-emitting element ES illustrated in FIG. 1 has, by way of example, a configuration in which the anode 11, the HIL 21, the HTL 22, the EML 23, the ETL 24, the EIL 25, and the cathode 13 are stacked on the substrate 2 in the stated order from the bottom.

However, this embodiment is not limited to this configuration. When the cathode 13 is the first electrode, and the anode 11 is the second electrode, as earlier described, the light-emitting element ES may have a configuration in which the cathode 13, the EIL 25 the ETL 24, the EML 23, the HTL 22, the HIL 21, and the anode 11 are stacked on the substrate 2 in the stated order from the bottom. Further, the following description is based on that the EL layer 12 has the foregoing configuration. However, the EL layer 12 may include a layer other than the foregoing; the EL layer 12 may have a configuration without at least one of the HIL 21, HTL 22, ETL 24, and EIL 25.

The HIL 21 is a layer having hole transportability, and that promotes hole injection from the anode 11 to the HTL 22. The HTL 22 is a layer having hole transportability, and that promotes hole transport from the HIL 21 to the EML 23. The EML 23 is a layer that emits light upon recombination of a hole, transported from the anode 11, and an electron, transported from the cathode 13. The EIL 25 is a layer having electron transportability, and that promotes electron injection from the cathode 13 to the ETL 24. The ETL 24 is a layer having electron transportability, and that promotes electron transport from the EIL 25 to the EML 23.

The stacked conformation of these EL layers 12 is non-limiting as long as it includes at least the EML 23, as described above; materials similar to known materials can be used as the materials of these EL layers 12.

A usable example of the material of the HIL 21 is, but not limited to, hole transport materials, such as a composite (PEDOT:PSS) of poly (3, 4-ethylenedioxythiophene) (PEDOT) and polystyrene sulfonic acid (PSS). These hole transport materials may be used alone, or in combination of two or more kinds as appropriate.

A usable example of the material of HTL 22 is hole transport materials, such as poly [(9,9-dioctylfluorenyl-2,7-diyl)-co-(4,4′-(N-4-sec-butylphenyl)) diphenylamine)] (TFB), poly[N,N′-bis(4-butylphenyl)-N,N′-bis(phenyl)-benzidine] (p-TPD), and polyvinyl carbazole (PVK). These hole transport materials may be used alone, or in combination of two or more kinds as appropriate.

A usable example of the material of the EML 23 is organic light-emitting materials, such as low-molecular fluorescence (or phosphorescent) dye. These organic light-emitting materials may be used alone, or in combination of two or more kinds as appropriate. However, a red organic light-emitting material is used for the red light-emitting elements. A green organic light-emitting material is used for the green light-emitting elements. A blue organic light-emitting material is used for the blue light-emitting elements.

A usable example of the material of the ETL 24 is electron transport materials, such as 1,3,5-tris(1-phenyl-1H-benzimidazol-2-yl)benzene (TPBi), bathophenanthroline (Bphen), (iv)tris(2,4,6-trimethyl-3-(pyridin-3-yl) phenyl) borane (3TPYMB). These electron transport materials may be used alone, or in combination of two or more kinds as appropriate.

A usable example of the material of the EIL 25 is electron transport materials, such as quinoline, perylene, phenanthroline, pyrazine, triazole, and their derivatives. It is noted that an electron transport material composed of an inorganic compound, such as lithium fluoride (LiF), may be used for the EIL 25. These electron transport materials may be used alone, or in combination of two or more kinds as appropriate.

FIG. 1 illustrates, by way of example, an instance where the HIL 21 is a common layer shared among all the subpixels SP, and where each of the HTL 22, EML 23, ETL 24, and EIL 25 is formed in an island shape for each subpixel SP. However, the display device 1 according to this embodiment is not limited to the foregoing. The HIL 21, the HTL 22, the ETL 24, and the EIL 25 may be formed in an island shape for each subpixel SP or may be shared among all the subpixels SP as long as the EML 23 is formed in an island shape for each subpixel SP.

It is noted that forming these layers into an island shape for each subpixel SP means, in the present disclosure, material supply for each subpixel SP without material supply between the openings BKa of the subpixels SP adjacent to each other. It is noted, on other hand, that forming these layers in common throughout all the subpixels SP means supplying the same material to all the subpixels SP including the spaces between the openings BKa of the subpixels SP adjacent to each other.

The sealing layer 4 has light transparency and includes, for example, a first inorganic sealing film, an organic sealing film, and a second inorganic sealing film in order from the bottom (i.e., on the light-emitting element layer 3). However, this is non-limiting; the sealing layer 4 may be composed of an inorganic sealing monolayer film, or a stack of five or more layers composed of an organic sealing film and an inorganic sealing film.

The inorganic sealing films can be composed of, for instance, a silicon oxide film, a silicon nitride film, or a silicon oxide nitride film, all of which are formed through chemical vapor deposition (CVD), or a stack of these films. The organic sealing film can be composed of, for instance, a photosensitive resin that can be applied, such as polyimide resin or acrylic resin.

Further, the sealing layer 4 may be sealing glass for instance. The light-emitting elements ES, which are sealed by the sealing layer 4, can be prevented from permeation of water, oxygen, or other substances.

The thickness of each layer of the display device 1 needs to be set appropriately in accordance with the layer's material or other things in such a manner that a desired optical-path length conforming to the color of emitted light can be obtained; the thickness is set in a non-limiting manner. The thickness of each layer of the display device 1 can be set in a manner similar to a known manner for instance.

### Effects

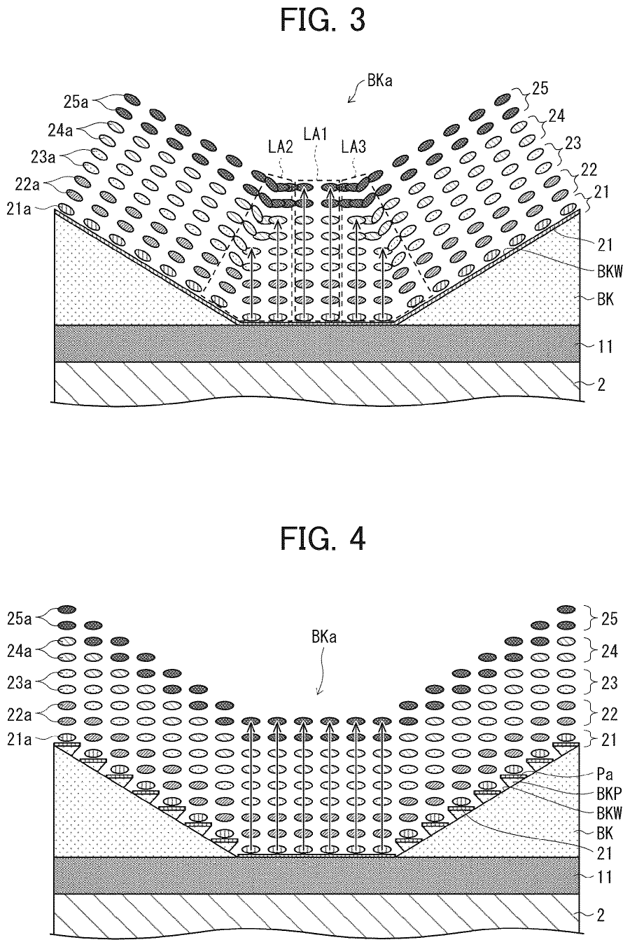

Effects of the display device 1 according to this embodiment will be described with reference to FIG. 3 and FIG. 4. FIG. 3 is a sectional view of the opening BKa of a comparative display device without the protrusions BKP on the bank BK and schematically illustrates how each organic molecule constituting the EL layer 12 accumulates. FIG. 4 is a sectional view of the opening BKa of the display device 1 according to this embodiment and schematically illustrates how each organic molecule constituting the EL layer 12 accumulates. It is noted that for convenience in description, FIG. 3 and FIG. 4 illustrate a part of the HIL 21 in the form of a film, and another part of the same in the form of organic molecules.

FIG. 3 and FIG. 4 show organic molecules 21a, which are organic molecules constituting the HIL 21. In addition, the drawings show organic molecules 22a, which are organic molecules constituting the HTL 22. The drawings show organic molecules 23a, which are organic molecules constituting the EML 23. The drawings show organic molecules 24a, which are organic molecules constituting the ETL 24. The drawings show organic molecules 25a, which are organic molecules constituting the EIL 25. It is noted that FIG. 3 and FIG. 4 illustrate the organic molecules 21a to 25a while enlarging them and reducing their numbers.

As illustrated in FIG. 3, when no protrusions BKP are provided on the bank BK, the individual organic layers are stacked on the inclined opening sidewall BKW of the bank BK, with the organic molecules 21a to 25a oriented obliquely along the opening sidewall BKW. As such, the molecule orientation of the organic molecules 21a to 25a is different between the first electrode not covered with the bank BK, which constitutes an emission region in plan view, and the top of the opening sidewall BKW of the bank BK. As a result, the organic molecules 21a to 25a near the edge of the bank BK in the opening BKa cannot be successfully stacked in a line in the direction of the normal to the substrate 2, thereby making some of the organic molecules 21a to 25a amorphous.

Here, let the center, LA1, of the foregoing emission region (i.e., the center of the first electrode not covered with the bank BK) in sectional view, as illustrated in FIG. 3, have a resistance Rc1. Further, let portions LA2 and LA3, each located outside the center LA1 and near the edge of the bank BK, as illustrated in FIG. 3, respectively have resistances Rc2 and Rc3.

At the center LA1, the accumulation directions of the organic molecules 21a to 25a (i.e., the growth directions of the individual organic layers) all coincide with the direction of the normal to the substrate 2, as illustrated in FIG. 3. On the other hand, at the portions LA2 and LA3 near the edge, the organic molecules 21a to 25a are oriented in various directions, thus disturbing the foregoing growth directions, thereby making some of the organic molecules 21a to 25a amorphous, as earlier described.

This results in Rc2>Rc1 and Rc3>Rc1. Accordingly, the portions LA2 and LA3 near the edge, which have high resistance, has reduced electric-charge mobility, thereby adversely affecting electron-and-hole carrier balance, light emission efficiency, and light extraction efficiency. This reduced electric-charge mobility makes a difference in light emission efficiency and a luminance difference between the center LA1, and the portions LA2 and LA3 near the edge.

Further, for example, when the HIL 21 is a common layer shared among all the subpixels SP, as described above, and no protrusions BKP are provided on the bank BK, as illustrated in FIG. 3, carriers are transported to the subpixels SP adjacent to each other via the common layer. This can cause electrical crosstalk, thus possibly causing stray light.

In this embodiment on the other hand, the individual organic molecules 21a to 25a, constituting the EL layer 12, accumulate, in the opening portion BKa, on the upper surface of the first electrode not covered with the bank BK and on upper surfaces Pa of the protrusions BKP, as illustrated in FIG. 4. As such, in this embodiment, the upper surface of the first electrode not covered with the bank BK, and the upper surfaces Pa of the protrusions BKP constitute surfaces on which the individual organic molecules 21a to 25a accumulate (i.e., a surface on which the EL layer 12 is formed) in the opening BKa.

Accordingly, in this embodiment, as illustrated in FIG. 4, the organic molecules 21a to 25a, constituting the EL layer 12 in the opening BKa, are accumulated on the foregoing accumulation surfaces perpendicularly to the accumulation surfaces while being oriented horizontally so that the direction of the long axes of these organic molecules 21a to 25a is in a horizontal direction.

Accordingly, the molecule orientations of the organic molecules 21a to 25a of the respective organic layers in each subpixel SP can align in this embodiment. This embodiment thus offers the resistance value Rc1 throughout the opening BKa, thus making no resistance difference in the opening BKa, thereby enabling uniform electric-charge mobility. For this reason, no such difference in light emission efficiency and no such luminance difference as those in the comparative display device illustrated in FIG. 3 occur in this embodiment.

Further, when the EL layer 12 is provided with such a common layer as the HIL 21 illustrated in FIG. 1, forming each protrusion BKP so as to have a reverse-tapered shape in sectional view, as illustrated in FIG. 1 and FIG. 4, provides the common layer disconnected into stages at the time of formation. Accordingly, no carriers are transported to the adjacent subpixels SP via the common layer, thus enabling avoidance of electrical crosstalk. Consequently, the display device 1 according to this embodiment can avoid stray light that results from electrical crosstalk.

It is noted that Patent Literature 1 is silent about a bank having an inclined opening sidewall and neither discloses nor suggests the disturbance of the molecule orientations near the bank's edge.

Patent Literatures 2 to 4 on the other hand neither disclose nor suggest the orientation directions of organic molecules. Patent Literature 2 is directed to solving thickness non-uniformity in an organic light-emitting layer that occurs when an ink containing an organic light-emitting material is applied into a region surrounded by a bank in all directions, and the applied ink is thus yanked to the bank's end by its surface tension. As such, Patent Literature 2 describes providing, on the substrate, a line-shaped first bank defining a line-shaped region, and a second bank placed within the line-shaped region, defining a pixel region, and being lower than the first bank. The first bank and the second bank have their horizontal upper surfaces and are each formed in a forward-tapered shape, and in plan view, the inclined surfaces of the first and second banks are exposed; these inclined surfaces constitute surfaces on which organic molecules accumulate. As such, the organic EL display panel described in Patent Literature 2 has the same problem as that in the comparative display device illustrated in FIG. 3.

Patent Literature 3 is directed to forming a plurality of protrusions on the bank's inclined opening sidewall of a display device. Each protrusion in Patent Literature 3 as well has a horizontal upper surface. However, Patent Document 3 has been made in view of a pinning phenomenon, where when a film is formed through a liquid phase method, liquid contraction resulting from drying is suppressed by a solute deposited at the liquid's edge. Patent Literature 3 aims to control a position at which the liquid material starts to be dried, by providing the bank with protrusions made of an inorganic material and having an affinity for liquid, and Patent Literature 3 does not reflect the orientation directions of organic molecules at all. As such, the display device described in Patent Literature 3 has a region from which the bank's inclined surface is exposed, in a location between the protrusions adjacent to each other in plan view; this inclined surface constitutes surfaces on which the organic molecules accumulate. Thus, the method described in Patent Literature 3 cannot solve the foregoing problem.

Patent Literature 4 discloses a display device including a bank having a flat upper surface, a flat bottom, and an inclined portion, and having periodic-stripe shaped asperities on the surface of the bank's inclined portion. Patent Literature 4 is directed to providing the bank's inclined portion with such an asperity conformation to thus form an asperity conformation on the inclined portion of an organic layer, the inclined portion of an upper electrode, which is a counter electrode, and the inclined portion of a sealing layer. Accordingly, light emitted in the organic layer, and guided through the layer while repeating total reflection without being extracted to the direction of the front of the display device causes irregular reflection due to the asperity conformation. As a result, reflected light smaller than a critical angle increases, improving the efficiency of light extraction to the direction of the front of the display device.

The asperity conformation in Patent Literature 4 is for subjecting light that is guided through individual layers while repeating total reflection, to irregular reflection, rather than for orienting the organic molecules horizontally.

Patent Literature 4 describes subjecting the bank on a lower electrode, which is a pixel electrode, to exposure to monochromatic light having a wavelength ranging from 300 to 500 nm, to thus generate a standing wave by interference of an incident wave and of a reflected wave from the lower electrode. This exposure with the standing wave causes a change in the bank's photosensitivity. As a result, an asperity conformation having a half period (λ/2) of a light-source wavelength, and reflecting the waveform of the standing wave is formed on the surface of the bank's inclined portion.

The asperity conformation formed in this way has, in principle, a wave shape reflecting the waveform of the standing wave, as earlier described, and thus has no horizontal surface. As such, the method described in Patent Literature 4 as well cannot solve the foregoing problem as well. In either case, Patent Literatures 1 to 4 are not directed to solving the problem and neither disclose nor suggest a light-emitting device in which organic molecules constituting an organic layer provided within the opening of a bank having an inclined opening sidewall are oriented horizontally, so that the light-emitting device emits light uniformly.

### Method for Manufacturing Display Device 1

A method for manufacturing the display device 1 will be next described.

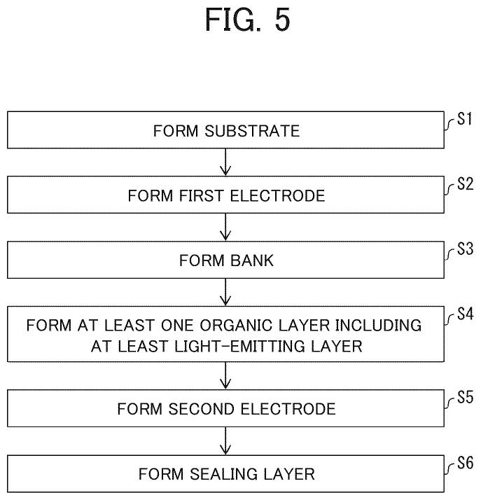

FIG. 5 is a flowchart showing an example of the method for manufacturing the display device 1 according to this embodiment.

The first process step (Step S1: a step of forming a substrate) in this embodiment is forming the substrate 2, as shown in FIG. 5. The next (Step S2: a step of forming a first electrode) is forming a first electrode, an example of which is the anode 11, as illustrated in FIG. 1 and FIG. 4. The next (Step S3: a step of forming a bank) is forming the bank BK. The next (Step S4: a step of forming an organic layer, a step of forming an EL layer) is forming, as the EL layer 12, at least one organic layer including at least the EML 23. The next (Step S5: a step of forming a second electrode) is forming the second electrode, an example of which is the cathode 13, as illustrated in FIG. 1. Accordingly, the light-emitting element layer 3 including the first electrode, bank BK, EL layer 12, and second electrode is formed onto the substrate 2. The next (Step S6: a step of forming a sealing layer) is forming the sealing layer 4.

Step S1 may include forming the substrate 2 by forming TFTs and other components onto an insulating substrate in correspondence with where the respective subpixels SP of the display device 1 are to be formed.

The first electrode is formed in an island shape for each subpixel SP, as earlier described. The first electrode is thus formed, in Step S2, in an island shape in correspondence with where each subpixel SP of the display device 1 is to be formed. The first electrode may be formed by forming a film made of the foregoing conductive material in a flat manner across all the subpixels SP, followed by patterning, through photolithography, this conductive material film into an island shape for each subpixel SP. Alternatively, the first electrode may be formed by pattern-forming the conductive material film into an island shape for each subpixel SP.

On the other hand, the second electrode, which is a common electrode, is formed in Step S5 by forming a film made of the foregoing conductive material, in common in a flat manner across all the subpixels SP.

It is noted that the formation of the conductive material films in Step S2 and Step 5 can use, but not limited to, physical vapor deposition (PVD), such as sputtering or vacuum evaporation, spin coating, ink-jet printing.

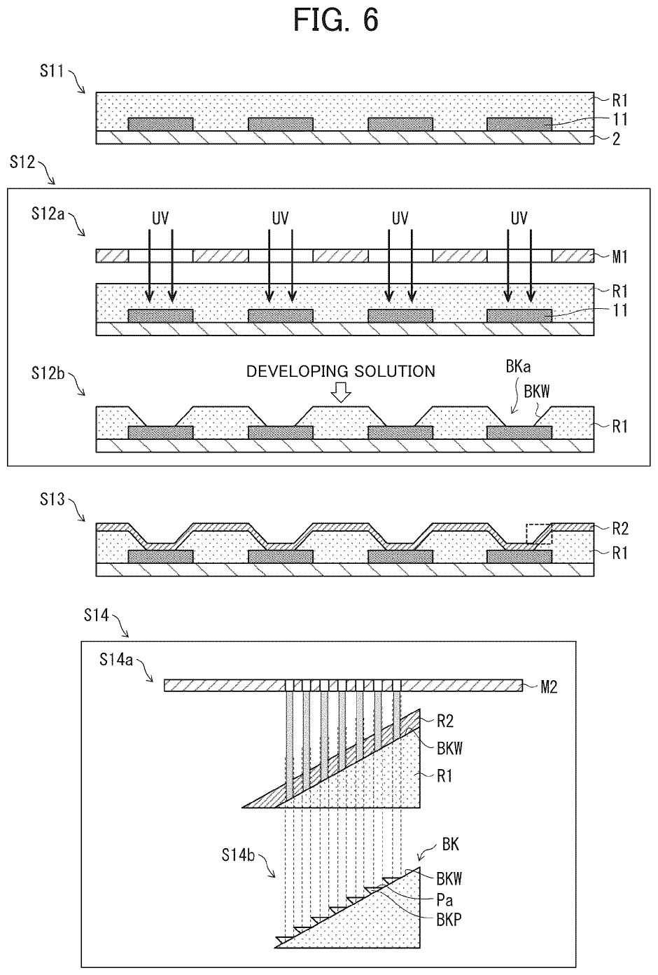

FIG. 6 is sectional views of an example of the bank in the process of being formed in the step (Step S3) shown in FIG. 5.

The step of forming the bank includes the first process step (Step S11: a step of forming a first resist film) of forming a first resist film R1 composed of a positive resist, and that constitutes the bank BK, so as to cover the first electrode, an example of which is the anode 11. It is noted that a positive photoresist will be referred to as a positive resist in the present disclosure.

The next (Step S12: a step of patterning the first resist film) is patterning the first resist film R1 so as to have the inclined opening sidewall BKW, and the opening BKa for exposing the upper surface of the first electrode, and to cover the edge of the first electrode.

The step of patterning the first resist film (Step S12) includes a step of subjecting the first resist film to exposure (Step S12a), and a step of subjecting the first resist film to development (Step S12b), as illustrated in FIG. 6.

In the step of subjecting the first resist film to exposure (Step S12a), the first resist film R1 disposed on the first electrode and in which the opening BKa is to be formed undergoes exposure. In the step of subjecting the first resist film to development (Step S12b), the first resist film R1 exposed in the step of subjecting the first resist film to exposure (Step S12a) undergoes development by the use of a developing solution.

This exposure uses a mask M1 with openings corresponding to portions of the first resist film R1 in which the openings BKa are to be formed.

A positive resist exposed to active radiation, such as ultraviolet (UV), increases solubility in a developing solution. By using a positive resist as the first resist film R1, the opening BKa having the inclined opening sidewall BKW, and having a reverse-tapered shape in sectional view is formed after the development.

The next (Step S13: a step of forming a second resist film) is forming a second resist film R2 composed of a negative resist onto the first resist film R1 patterned in the step of patterning the first resist film. It is noted that a negative photoresist will be referred to as a negative resist in the present disclosure.

The next (Step S14: a step of patterning the second resist film) is patterning the second resist film R2 so as to have a plurality of protrusions BKP formed along the opening sidewall BKW in a staircase manner, and each having the horizontal upper surface Pa.

In the step of patterning the second resist film (Step S14), the second resist film R2 preferably undergoes patterning in such a manner that, as earlier described, the plurality of protrusions BKP have a reverse-tapered shape in sectional view.

The step of patterning the second resist film (Step S14) includes a step of subjecting the second resist film to exposure (Step S14a), and a step of subjecting the second resist film to development (Step S14b), as illustrated in FIG. 6.

In the step of subjecting the second resist film to exposure (Step S14a), the second resist film R2 on the opening sidewall BKW undergoes exposure. In the step of subjecting the second resist film to development (Step S14b), the second resist film R2 exposed in the step of subjecting the second resist film to exposure (Step S14a) undergoes development by the use of a developing solution.

A negative photoresist exposed to light decreases solubility in a developing solution. Thus, the step of subjecting the second resist film to exposure (Step S14a) uses a mask M2 to subject the second resist film R2 on the opening sidewall BKW to exposure. As the mask M2, a gradation mask having, in a location overlapping the opening sidewall BKW above, a translucent region that allows part of active radiation (e.g., UV) to pass is used. As described above, subjecting the negative resist to exposure by the use of the gradation mask can form the plurality of protrusions BKP each having an inclined surface whose end surface has a reverse-tapered shape, and each having the horizontal upper surface Pa onto the opening sidewall BKW in accordance with the interference of light and the resolution of an exposing machine.

It is noted that the plurality of protrusions BKP may partly overlap as long as only the upper surface of the first electrode, an example of which is the anode 11, and the upper surfaces Pa of the protrusions BKP are exposed when viewed from immediately above, as earlier described. That is, the leading edge of the protrusion BKP placed at the upper stage between the protrusions BKP adjacent to each other may be located directly above the trailing edge of the protrusion BKP at the lower stage, or between the leading edge and trailing edge of the protrusion BKP at the lower stage.

It is noted that the leading edge of the protrusion BKP herein is an edge of the protrusion BKP close to the middle of the emission region, and that the trailing edge of the protrusion BKP herein is an edge of the protrusion BKP close to the opening sidewall BKW, which is composed of the first resist film R1.

In Step S4, evaporation, such as vacuum evaporation, can be used for forming the organic layer, which is the EL layer 12.

In this embodiment, the protrusions BKP are provided on the bank BK, as earlier described, and thus, the organic molecules 21a to 25a are accumulated on the accumulation surfaces perpendicularly to the accumulation surfaces while being horizontally oriented so that the directions of their long axes are all in a horizontal direction. Consequently, this embodiment can provide the display device 1 and a method for manufacturing the same in which the organic molecules 21a to 25a, constituting the EL layer 12 provided within the opening BKa of the bank BK having the inclined opening sidewall BKW, are oriented horizontally, so that the display device 1 emits light uniformly.

### Second Embodiment

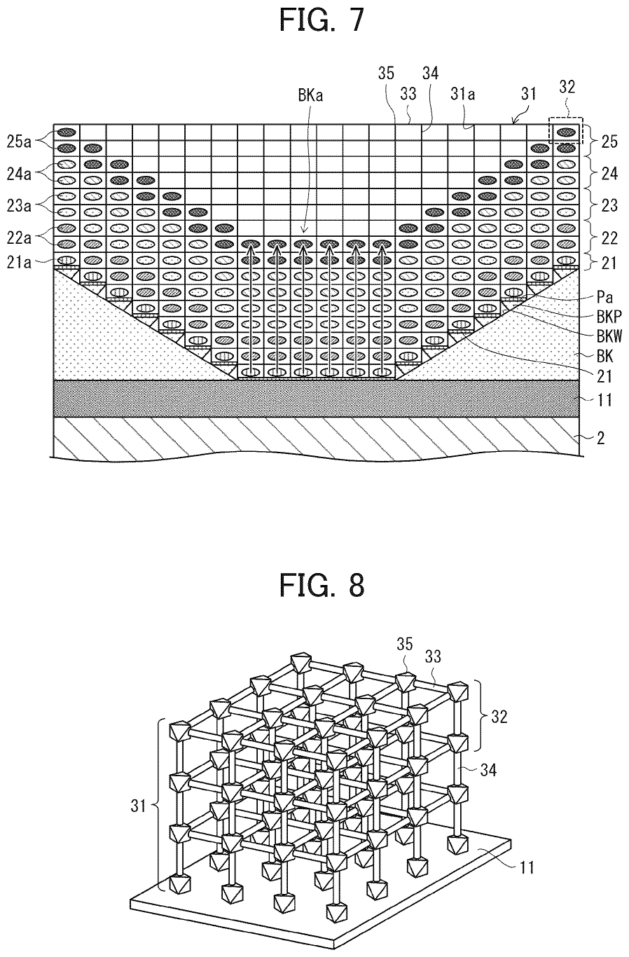

Another embodiment of the present disclosure will be described with reference to FIG. 7 to FIG. 12. It is noted that for convenience in description, components having the same functions as those of components described in the first embodiment will be denoted by the same signs, and that their description will not be repeated.

FIG. 7 is a sectional view of the opening BKa of the display device 1 according to this embodiment and schematically illustrates how each organic molecule constituting the EL layer 12 accumulates.

It is noted that the following describes, by way of example, an instance where, like those in the first embodiment, the anode 11 is a first electrode (lower electrode), and the cathode 13 is a second electrode (upper electrode), as illustrated in FIG. 7. However, in this embodiment as well, the cathode 13 may be the first electrode, and the anode 11 may be the second electrode.

The display device 1 according to this embodiment has a domain restricting structure 31, as illustrated in FIG. 7, disposed on the upper surface of the first electrode exposed from the opening BKa of the bank BK and on the upper surfaces of the protrusions BKP, and partitioning the accumulation regions of organic molecules horizontally adjacent to each other, to restrict the accumulation direction of these organic molecules. The display device 1 according to this embodiment is the same as the display device 1 according to the first embodiment except this point.

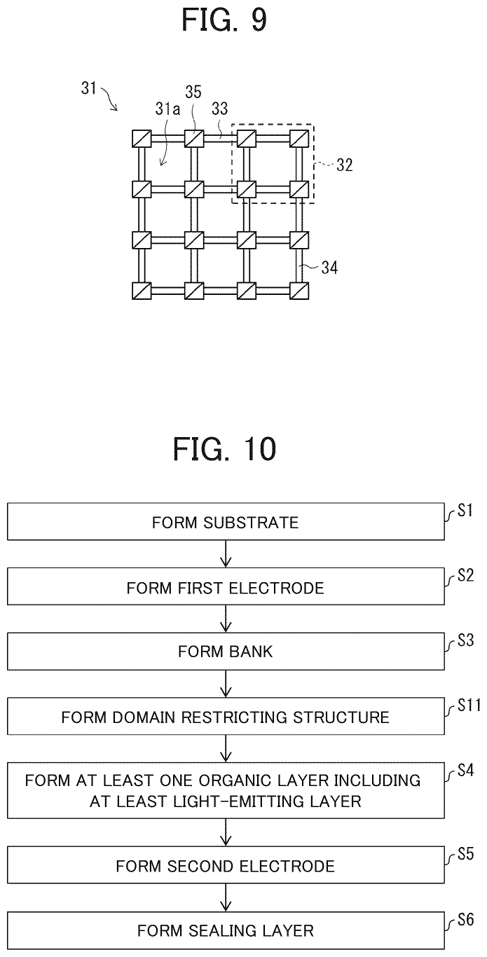

FIG. 8 is a perspective view of the schematic configuration of main components of the domain restricting structure 31, and FIG. 9 is a plan view of the schematic configuration of the main components of the domain restricting structure 31. It is noted that FIG. 8 and FIG. 9 illustrate, by way of example, an instance where an underlayer is the first electrode, and the domain restricting structure 31 is provided on the anode 11, which is the first electrode; this configuration holds true for an instance where the underlayer is the protrusions BKP or the cathode 13.

As illustrated in FIG. 7 to FIG. 9, the domain restricting structure 31 has communicating holes 31a housing the organic molecules 21a to 25, and disposed perpendicularly to the upper surface of the first electrode exposed from the opening BKa and to the upper surfaces Pa of the protrusions BKP (i.e., in the direction of the normal to the substrate 2). The domain restricting structure 31 thus partitions the accumulation regions of the organic molecules 21a to 25a horizontally adjacent to each other, to restrict the accumulation direction of the organic molecules 21a to 25a.

The domain restricting structure 31 has a rigid three-dimensional mesh conformation for instance, with a plurality of cubic lattices 32 stacked perpendicularly to the upper surface of the first electrode exposed from the opening BKa and to the upper surfaces of the protrusions BKP.

Each cubic lattice 32 has such a size as to surround a corresponding one of the organic molecules constituting the EL layer 12. It is noted that the cubic lattices 32 may be a rectangular-parallelepiped frame or a cube frame.

In this embodiment, providing such a domain restricting structure 31 in the opening BKa can provide the opening BKa with a plurality of oblong nano-channels (nano-spaces) that can house the organic molecules 21a to 25a and arrange them in the foregoing normal direction.

The domain restricting structure 31 can be achieved by a porous metal-organic framework (MOF) for instance.

Each cubic lattice 32 includes a first unit 33 constituting the horizontal shaft of the cubic lattice 32, and a second unit 34 constituting the vertical shaft of the cubic lattice 32.

Each cubic lattice 32 also contains a plurality of metals 35. The first unit 33 and the second unit 34 are linkers (ligands) and couple the plurality of metals 35 together within the cubic lattice 32.

The first unit 33 has, for instance, a molecular chain having a cross shape, and includes the molecular chain of a first conjugated compound having a lone pair at its four ends. The second unit 34 includes, for instance, a molecular chain of a second conjugated compound having a chain shape, and having a lone pair at two ends of its main chain. These first conjugated compound and second conjugated compound are each a multidentate organic ligand (multidentate ligand) and each function as a Lewis base.

The first unit 33 can be composed of a compound that is expressed by Expression (1) below, where n denotes an integer ranging from zero to five.

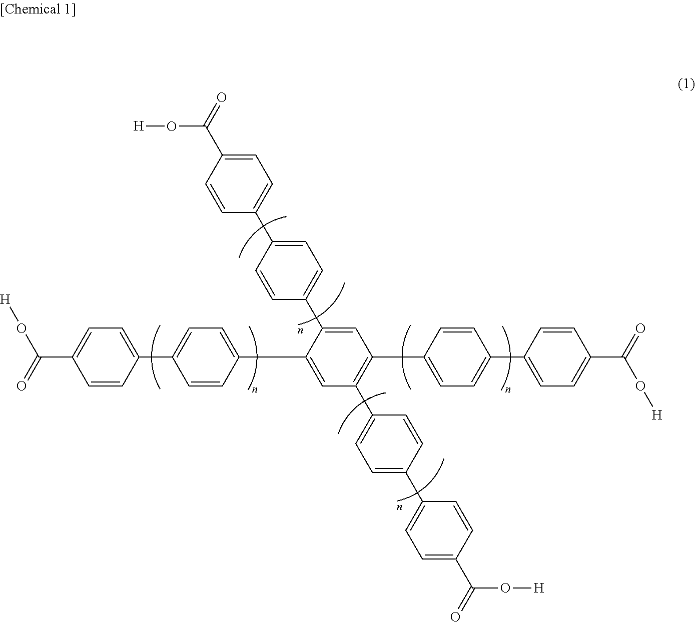

In other words, the first conjugated compound may include a compound that is expressed by Expression (1) above, and the first unit 33 may include a molecular chain of a compound that is expressed by Expression (1) above.

Further, the second unit 34 can be composed of a compound that is expressed by Expression (2) below, where m denotes an integer ranging from zero to five.

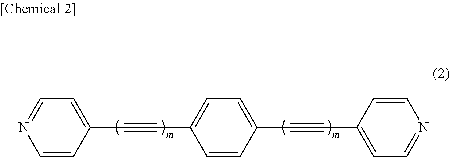

In other words, the second conjugated compound may include a compound that is expressed by Expression (2) above, and the second unit 34 may include a molecular chain of a compound that is expressed by Expression (2) above.

For instance, the compound that is expressed by Expression (1) above contains an oxygen atom having a lone pair that can coordinate with the metals 35. In addition, the compound that is expressed by Expression (2) above contains a nitrogen atom having a lone pair that can coordinate with the metals 35. The compound that is expressed by Expression (1) above and the compound that is expressed by Expression (2) above each donate electrons to the metals 35 to thus form a metal complex. The compound that is expressed by Expression (1) above is bonded with the metals 35 by a lone pair of oxygen, and the compound that is expressed by Expression (2) above is bounded with the metals 35 by a lone pair of nitrogen. At this time, the compound that is expressed by Expression (1) above and the compound that is expressed by Expression (2) above are bonded with the same metal 35, thereby forming a three-dimensional mesh conformation.

The domain restricting structure 31 preferably has conductivity. Accordingly, the first conjugated compound is preferably a conductive material. Likewise, the second conjugated compound is preferably a conductive material. The compound that is expressed by Expression (1) above and the compound that is expressed by Expression (2) above each have conductivity.

However, this embodiment is not limited to this configuration. The domain restricting structure 31 may be an insulator, and the first conjugated compound may be an insulating material. Likewise, the second conjugated compound may be an insulating material. The first unit 33 and the second unit 32 are linkers, as earlier described, and are each composed of a molecular chain of the foregoing compound. Hence, the first unit 33 and the second unit 34 have such a small thickness that holes and electrons can be conducted sufficiently by tunneling even when the first conjugated compound and the second conjugated compound are insulating materials.

Further, the metals 35 are non-limiting as long as they are metal elements that can form a complex. Examples of the metals 35 include, by not limited to, the following: transition metals, such as copper (Cu) and zinc (Zn); poor metals, such as indium (In); and lanthanoids, such as europium (Eu), terbium (Tb), and Eu-Tb. It is noted that poor metals are metal elements within so-called P-block elements, which belong to Group 13 to Group 18. It is noted that the metals 35 may be metal ions, or the metals 35 may be a metal cluster or a metal complex.

### Method for Manufacturing Display Device 1

A method for manufacturing the display device 1 will be next described with reference to FIG. 10 to FIG. 12.

FIG. 10 is a flowchart showing an example of the method for manufacturing the display device 1 according to this embodiment.

As shown in FIG. 10, the method for manufacturing the display device 1 according to this embodiment includes a step (Step S11) of forming a domain restricting structure, in which the domain restricting structure 31 is formed after Step S3, i.e., the formation of the bank BK, and before Step S4, i.e., the formation of the EL layer 12. Except for this point, the method for manufacturing the display device 1 according to this embodiment is the same as the method for manufacturing the display device 1 according to the first embodiment.

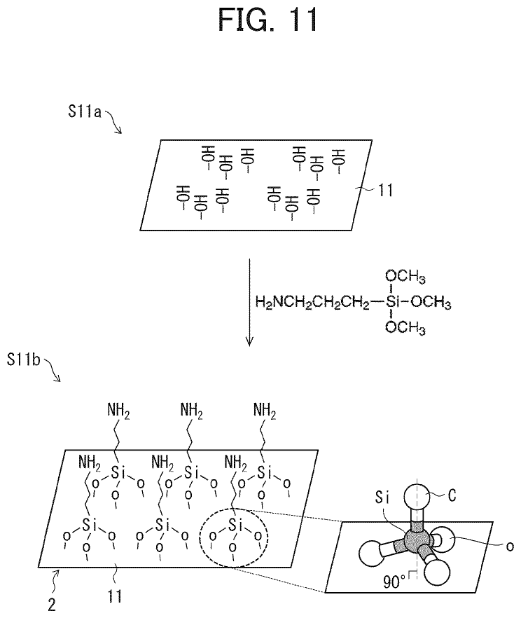

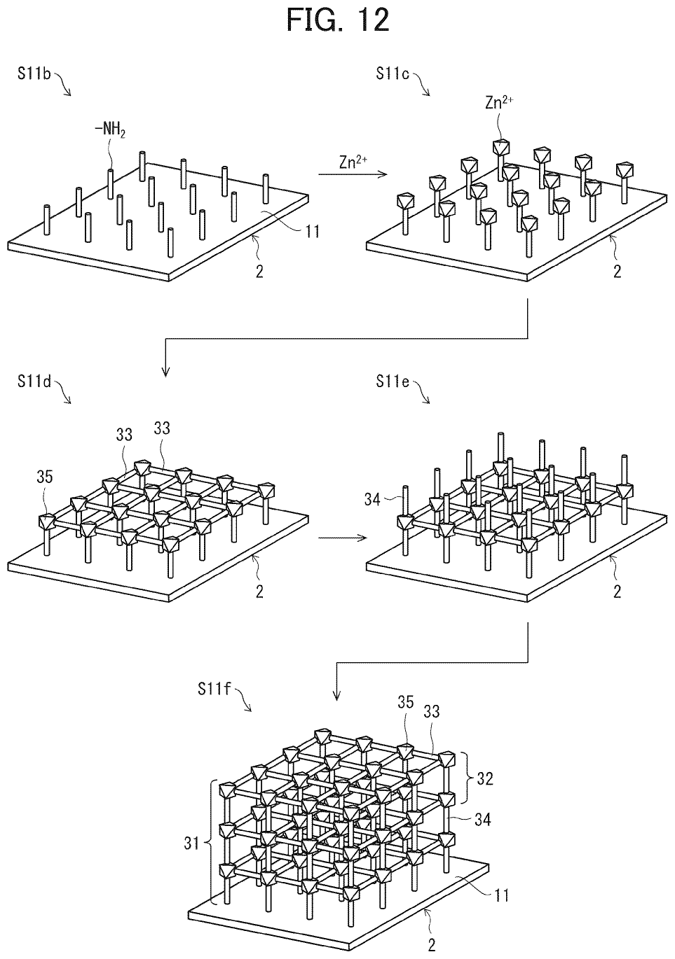

FIG. 11 is sectional views of the domain restricting structure in the process of being formed in exemplified part of the step (Step S11) shown in FIG. 10. FIG. 12 is other sectional views of the domain restricting structure in the process of being formed in exemplified part of the step (Step S11) shown in FIG. 10. It is noted that the following describes a specific example of how to form the domain restricting structure 31. However, materials and conditions that will be described below are mere examples and are not limited to the following conditions alone.

The step of forming the domain restricting structure includes the first process step of, for instance, as illustrated in S11a in FIG. 11, irradiating, with ozone plasma for 5 minutes, the opening BKa of the bank BK on the substrate 2 on which the first electrode, an example of which is the anode 11, and the bank BK are provided. This (Step S11a) forms a hydroxy (—OH) group onto a region of the substrate 2 irradiated with ozone plasma (to be specific, onto the upper surface of the first electrode and the upper surfaces Pa of the protrusions BKP).

The next is subjecting the substrate 2 to 20-minute reflux within a mixed solution containing 3-aminopropyl-trimethoxysilane (3-APTMS) that is expressed by Expression (3) below and octanol at a 1:100 volume ratio.

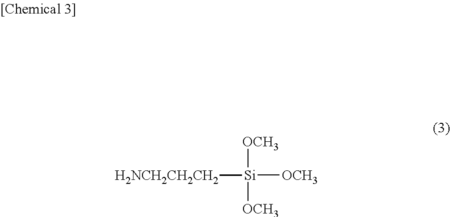

The next is rinsing the substrate 2 with hexane and pure water (H₂O), and drying the substrate 2 in an oven at 70° C. for 15 minutes. Accordingly, the 3-APTMS reacts with the hydroxy group formed in the ozone plasma processing, to be thus, as illustrated in S11b in FIG. 11 and FIG. 12, patterned (Step S11b) into a column shape onto the underlayer of the substrate 2. It is noted that for convenience in illustration, FIG. 11 and FIG. 12 illustrate, by way of example, an instance where the underlayer is the anode 11.

At this time, the chemical bonding of Si forms four sp³ hybrid orbits. Three of these four sp³ hybrid orbits are chemically connected to the surface of the underlayer. The remaining one has an amino (—NH₂) group at its end and is oriented perpendicularly to the underlayer.

The next is immersing the substrate 2 provided with the amino group, as shown in S11b in FIG. 11 and FIG. 12, into a metal-ion solution, which is herein a 0.1-mol/m³ zinc acetate solution, for 5 minutes in the oven at 40° C., to thus cause the amino group to react with metal ions (Zn²⁺). The next (Step S11c) is removing the remaining metal ions (Zn²⁺) through rinse with ethanol.

The next is immersing, for 10 minutes, the substrate 2 into a 2-μmol/L ethanol solution containing a first conjugated compound, an example of which is a compound that is expressed by Expression (1) above, (hereinafter, referred to as a first-conjugated-compound solution), to cause the first conjugated compound to react with the metal ions (Zn²⁺). The next is removing the remaining metal ions (Zn²⁺) through rinse with ethanol. Accordingly, the first unit 33 is formed (Step S11d).

The next is immersing, for 10 minutes, the substrate 2 with the first unit 33 formed thereon into a 2-μmol/L ethanol solution containing a second conjugated compound, an example of which is a compound that is expressed by Expression (2) above, to cause the second conjugated compound to react with the metal ions (Zn²⁺). The next is removing the remaining metal ions (Zn²⁺) through rinse with ethanol. Accordingly, the second unit 34 is formed (Step S11e).

It is noted that the conditions on the reaction in Step S11d and Step S11e, such as the concentrations of the respective first-conjugated-compound solution and second-conjugated-compound solution, and the time for causing the first conjugated compound and second conjugated compound to react with the metal ions, are non-limiting. However, to form a three-dimensional mesh conformation without defects, deformations, and other things, the first-conjugated-compound solution and the second-conjugated-compound solution desirably have the same concentration. In addition, for the same reason, the time for causing the first conjugated compound to react with the metal ions, and the time for causing the second conjugated compound to react with the metal ions are desirably set to be same. Further, removing unreacted metal ions through rinse as earlier described is also one desirable condition for forming a three-dimensional mesh conformation without defects, deformations, and other things.

In this embodiment, the substrate 2 undergoes a cycle of the following repeatedly by a desired number of cycles: (1) 5-minute immersion into a zinc acetate solution, followed by rinse; (2) 10-minute immersion into the first-conjugated-compound solution, followed by rinse; and (3) 10-minute immersion into the second-conjugated-compound solution, followed by rinse.

In other words, the process returns to foregoing Step S11c after Step S11e and repeats Steps S11c to Step S11e until the domain restricting structure 31 reaches a desired height. This (Step S11f) forms, as illustrated in S11f in FIG. 12, the domain restricting structure 31 with the plurality of cubic lattices 32 stacked perpendicularly to the upper surface of the first electrode, constituting the underlayer, and to the upper surfaces of the protrusions BKP.

In this embodiment, repeating the foregoing cycle increases the number of stacked cubic lattices 32 (i.e., the thickness of the domain restricting structure 31). For instance, let the cycle be repeated 200 times by the use of a compound that is expressed by Expression (1), where n is equal to zero, as the first conjugated compound, and a compound that is expressed by Expression (2), where m is equal to one, as the second conjugated compound. Accordingly, the domain restricting structure 31 having a thickness (height) of 100 nm can be formed.

The size of each cubic lattice 32 can be regulated as appropriate by, for instance, changing the side's length of the cubic lattice 32 (i.e., the length of the first unit 33, and the length of the second unit 34), such as by regulating a repetition unit number denoted by n or m. The domain restricting structure 31, although desirably adjusted in such a manner that a single organic molecule is included in a single cubic lattice 32, may be adjusted in such manner that a plurality of organic molecules are included in a single cubic lattice 32.

The first unit 33, constituting the horizontal shaft of each cubic lattice 32, has a length of, for instance, 1 to 2 nm by way of example. The second unit 34, constituting the vertical shaft of each cubic lattice 32, has a length of, for instance, 0.5 to 2 nm by way of example. Further, the domain restricting structure 31 has a thickness of, for instance, 200 to 300 nm by way of example, depending, but not limited to, on the number of stacked layers of the EL layer 12 and the layer configuration of the same, and on the inclination angle θ of the bank BK.

### Effects

In this embodiment, the protrusions BKP are provided on the inclined opening sidewall BKW of the bank BK, so that an MOF, which is herein the domain restricting structure 31, can grow in the direction of the normal to the substrate 2, within the entire opening BKa including the opening sidewall BKW.

In this embodiment, Step S11 is performed, in which the domain restricting structure 31 is formed, followed by Step S4, in which the EL layer 12 is formed, as described above. This enables the organic molecules 21a to 25a to be housed in the respective nano-channels of the domain restricting structure 31, and to be arranged in the normal direction.

In this embodiment, the domain restricting structure 31 is provided in the opening BKa of the bank BK, so that the organic molecules 21a to 25a can be stacked in a line in the direction of the normal to the substrate 2 at, for instance, a lower evaporation temperature and a lower evaporation rate than those in the first embodiment while being oriented horizontally. This increases a margin of these evaporation conditions.

It is noted that this embodiment has described an instance where the domain restricting structure 31 has such a three-dimensional mesh conformation as described above. However, as earlier described, the domain restricting structure 31 needs to be able to partition the accumulation regions of the organic molecules 21a to 25a horizontally adjacent to each other, and to enable the organic molecules 21a to 25a to be stacked in a line in the direction of the normal to the substrate 2 while being oriented horizontally. Thus, that the domain restricting structure 31 has such a three-dimensional mesh conformation as described above is one means for forming the domain restricting structure 31; it is not essential that the domain restricting structure 31 be a stack of the cubic lattices 32. The domain restricting structure 31 needs to have a conformation having communicating holes housing the organic molecules 21a to 25a, and disposed perpendicularly to the upper surface of the first electrode exposed from the opening BKa and to the upper surfaces Pa of the protrusions BKP.

The domain restricting structure 31 may thus have a configuration in which, for instance, only the second unit 34 is bonded with the metals 35. The second unit 34 in this case may be a unidentate organic ligand or a bidentate organic ligand.

### Modification

The first embodiment and the second embodiment have described, by way of example, an instance where a light-emitting device is the display device 1. However, these embodiments are not limited to this configuration. The light-emitting device may be such a display device as the display device 1, or such a light-emitting element as the light-emitting element ES.

The present disclosure is not limited to the foregoing embodiments. Various modifications can be made within the scope of the claims. An embodiment that is obtained in combination as appropriate with the technical means disclosed in the respective embodiments is also included in the technical scope of the disclosure. Furthermore, combining the technical means disclosed in the respective embodiments can form a new technical feature.

1. A light-emitting device comprising:
a first electrode;
a bank covering an edge of the first electrode, and having an opening from which an upper surface of the first electrode is exposed, the opening having an opening sidewall that is inclined;
at least one organic layer provided within the opening and including at least a light-emitting layer; and
a second electrode provided on the at least one organic layer,
wherein the bank has a plurality of protrusions having upper surfaces that are horizontal, and formed in a staircase manner along the opening sidewall in such a manner that accumulation surfaces of organic molecules constituting the at least one organic layer are all horizontal, and
the organic molecules are accumulated on the accumulation surfaces perpendicularly to the accumulation surfaces while being oriented horizontally so that a direction of long axes of the organic molecules is in a horizontal direction.

2. The light-emitting device according to claim 1, wherein the plurality of protrusions have a reverse-tapered shape in a sectional view.

3. The light-emitting device according to claim 1, comprising
a domain restricting structure disposed on the upper surface of the first electrode exposed from the opening and on the upper surfaces of the plurality of protrusions, and partitioning accumulation regions of the organic molecules horizontally adjacent to each other, to restrict an accumulation direction of the organic molecules,
wherein the domain restricting structure has communicating holes housing the organic molecules, and disposed perpendicularly to the upper surface of the first electrode exposed from the opening and to the upper surfaces of the plurality of protrusions.

4. The light-emitting device according to claim 3, wherein the domain restricting structure has a three-dimensional mesh conformation with a plurality of cubic lattices stacked perpendicularly to the upper surface of the first electrode exposed from the opening and to the upper surfaces of the plurality of protrusions.

5. The light-emitting device according to claim 4, wherein each of the plurality of cubic lattices has such a size as to surround a corresponding one of the organic molecules.

6. The light-emitting device according to claim 4, wherein
each of the plurality of cubic lattices includes a first unit constituting a horizontal shaft of the cubic lattice, and a second unit constituting a vertical shaft of the cubic lattice,
the first unit has a molecular chain having a cross shape and includes the molecular chain of a first conjugated compound having a lone pair at four ends, and
the second unit includes a molecular chain of a second conjugated compound having a chain shape, and having a lone pair at two ends of a main chain.

7. The light-emitting device according to claim 6, wherein the first conjugated compound includes a compound that is expressed by the following Expression (1), where n denotes an integer ranging from zero to five:

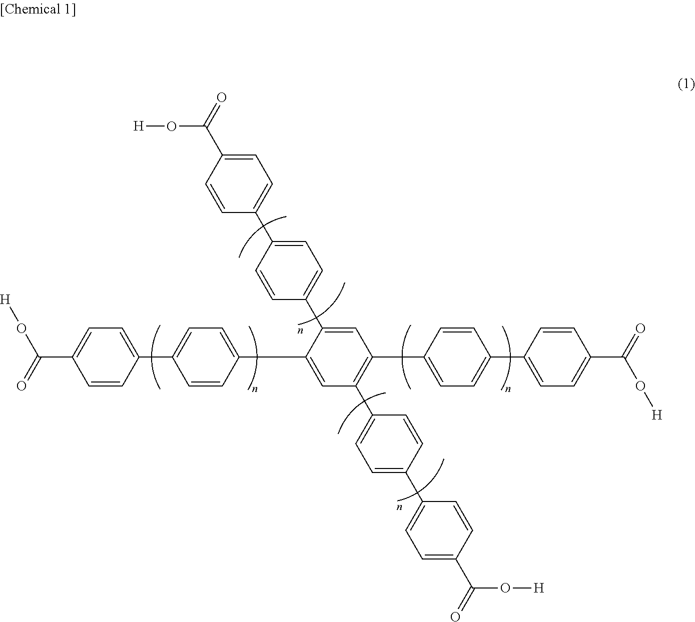

8. The light-emitting device according to claim 6, wherein the second conjugated compound includes a compound that is expressed by the following Expression (2), where m denotes an integer ranging from zero to five:

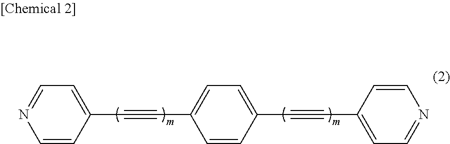

9. The light-emitting device according to claim 6, wherein
each of the plurality of cubic lattices contains a plurality of metals, and
the first unit and the second unit are linkers and couple the plurality of metals together within the cubic lattice.

10. The light-emitting device according to claim 3, wherein the domain restricting structure has conductivity.

11. The light-emitting device according to claim 1, wherein
the light-emitting device is a display device having a plurality of subpixels,
the bank has the opening for each of the plurality of subpixels,
the at least one organic layer includes a common layer provided between the first electrode and the light-emitting layer, and shared among the plurality of subpixels, and
the common layer is disconnected for each of the plurality of protrusions to form stages.

12. A method for manufacturing the light-emitting device according to claim 1, the method comprising the steps of:
forming the first electrode;
forming the bank;
forming the at least one organic layer; and
forming the second electrode,
wherein the step of forming the bank includes
a step forming a first resist film composed of a positive resist, so as to cover the first electrode,
a step of patterning the first resist film so as to have the opening sidewall that is inclined and have the opening from which the upper surface of the first electrode is exposed, and so as to cover the edge of the first electrode,
a step of forming a second resist film composed of a negative resist onto the first resist film patterned in the step of patterning the first resist film, and
a step of patterning the second resist film so as to have the plurality of protrusions having upper surfaces that are horizontal, and formed in a staircase manner along the opening sidewall.

13. The method for manufacturing the light-emitting device according to claim 12, wherein the step of patterning the second resist film includes patterning the second resist film in such a manner that the plurality of protrusions have a reverse-tapered shape in a sectional view.

14. The method for manufacturing the light-emitting device according to claim 12, further comprising
a step of forming, before the step of forming the at least one organic layer, a domain restricting structure onto the upper surface of the first electrode exposed from the opening and onto the upper surfaces of the plurality of protrusions, the domain restricting structure having communicating holes for housing the organic molecules, and being disposed perpendicularly to the upper surface of the first electrode exposed from the opening and to the upper surfaces of the plurality of protrusions, the domain restricting structure partitioning accumulation regions of the organic molecules horizontally adjacent to each other, to restrict an accumulation direction of the organic molecules.
